(19) United States
(12) Patent Application Publication
(10) Pub. No.: US 2026/0136623 A1
(43) Pub. Date: May 14, 2026

(54) METHOD FOR MANUFACTURING INTEGRATED STRUCTURE OF METAL-GATE MOS TRANSISTOR

(71) Applicant: Shanghai Huali Integrated Circuit Corporation, Shanghai (CN)

(72) Inventors: Zhi TIAN, Shanghai (CN); Duo SHAN, Shanghai (CN)

(73) Assignee: Shanghai Huali Integrated Circuit Corporation, Shanghai (CN)

(21) Appl. No.: 19/282,856

(22) Filed: Jul. 28, 2025

(30) Foreign Application Priority Data
Nov. 13, 2024 (CN) 202411622783.7

(51) Int. Cl. H01L 21/28; H01L 21/02; H01L 21/308

(52) U.S. Cl. CPC H10D 64/01332; H10P 14/6308; H10P 50/691; H10P 70/23

(57) ABSTRACT

The present application discloses a method for manufacturing an integrated structure of a metal-gate MOS transistor. Through a dry etching process, a medium-voltage device silicon recess is formed, and through a thermal oxidation process, a sacrificial oxide layer is formed on a bottom of the medium-voltage device silicon recess, thereby consuming silicon damaged by dry etching in the medium-voltage device silicon recess. Then, through a wet etch process, a hard mask layer, pad oxide layers in a low-voltage and a high-voltage region, and the sacrificial oxide layer in a medium-voltage region are removed. A thick oxide layer is then grown as a gate oxide layer of a medium-voltage device. The manufacturing method in the present application is fully compatible with existing processes and can reduce an effect of induced drain leakage without adding additional masks, thereby achieving an objective of reducing static power consumption of a metal-gate medium-voltage device.

### CROSS-REFERENCE TO RELATED APPLICATIONS

This application claims priority to Chinese patent application No. 202411622783.7, filed on November 13, 2024, the disclosure of which is incorporated herein by reference in its entirety.

### TECHNICAL FIELD

The present application relates to semiconductor manufacturing technologies, and in particular, to a method for manufacturing an integrated structure of a metal-gate MOS transistor.

### BACKGROUND

As the size of a metal oxide semiconductor (MOS) device is reduced, gate leakage becomes increasingly obvious exerting a more severe impact on the reliability of both the MOS device and a circuit. Since many MOS devices are in an off state for most of their practical operation time, a reliability of an off-state oxide layer is particularly critical. As a gate oxide layer of the MOS device is thinner and thinner, gate-induced drain leakage (GIDL) caused by band-to-band tunneling (BTBT) during the off state of the MOS device is increasingly larger, and has become one of the primary factors limiting the reliability and lifetime of the MOS device and circuit. Therefore, mitigating the impact of the GIDL effect is crucial for reducing the static power consumption of the MOS device.

Currently, the primary process manner to reduce the impact of GIDL include: increasing a thickness of a gate oxide layer, reducing the overlap between a lightly doped drain (LDD) and a gate, optimizing LDD doping conditions, increasing a spacer width to enlarge the distance between a drain and a gate, increasing a resistance at overlap region between a drain terminal and a gate to reduce an electric field strength at the gate terminal, and improving an interface quality at the overlap. However, solutions for a specific process are still under research.

In a typical high-voltage (HV) product, high-voltage (HV), medium-voltage (MV), and low-voltage (LV) devices are integrated. The medium-voltage (MV) device typically serves as input/output (IO) devices. Unlike a structure of an MOS device under a traditional silicon gate process, an MOS device under a metal gate process requires that tops of metal gates for HV, MV, and LV devices have a consistent height since a chemical mechanical polishing (CMP) process for the metal gate exists in a metal gate fabrication process. Since the MV device has a thicker oxide layer, a silicon recess (Si-Recess) process is necessary in an MV region.

In the related art, in a manufacturing process for the thick oxide layer of the MV device, a required thick oxide layer for the MV device is directly grown directly after the silicon recess process. The thick oxide layer is in direct contact with silicon (Si) after dry etching. Impurities and damage introduced by the dry etching remain present. Damage defects exist at an interface of an ate-drain overlap region. Electrons in the silicon produces band-to-band tunneling between a conduction band and a valence band, leading to severe GIDL in the MV device. The GIDL is one of primary factors affecting a static leakage current of an MOS device, which also causes a problem that the medium-voltage MOS device has high static power consumption.

### BRIEF SUMMARY

A method for manufacturing an integrated structure of a metal-gate MOS transistor provided in the present application includes the following steps:

S1. forming a pad oxide layer 110 on a silicon substrate 100;

the silicon substrate 100 being divided into a high-voltage device region 101, a medium-voltage device region 102, and a low-voltage device region 103 through a Shallow trench isolation 104;

S2. forming a hard mask layer 120 on the pad oxide layer 110;

S3. coating a photoresist 140, followed by photolithograph and dry etching to remove a hard mask layer 120, a pad oxide layer 110, and a top of a silicon substrate 100 in the medium-voltage device region 102 to form a medium-voltage device silicon recess 1021;

S4. forming a sacrificial oxide layer 130 on a bottom of the medium-voltage device silicon recess 1021 through a thermal oxidation process;

S5. removing the photoresist 140, followed by a wet process to remove the hard mask layer 120, the pad oxide layer 110 in the low-voltage region and the high-voltage region, and the sacrificial oxide layer 130 in the medium-voltage device silicon recess 1021;

S6. forming a medium-voltage thick gate oxide layer 150, an upper surface of the medium-voltage thick gate oxide layer 150 within the medium-voltage device silicon recess 1021 being not lower than an upper surface of the silicon substrate 100; and

S7. performing a subsequent process to complete manufacturing of the integrated structure of the metal-gate MOS transistor.

In some embodiments, in step S1, light-doped drain 106 ion implantation is performed in a silicon substrate 100 of the medium-voltage device region 102 adjacent to the Shallow trench isolation 104.

In some embodiments, in step S1, a zero mark is formed on the pad oxide layer 110, the pad oxide layer 110 is used as an alignment layer for the subsequent photolithography.

In some embodiments, in step S2, SIN is deposited on the pad oxide layer 110 to form a hard mask layer 120.

In some embodiments, in step S6, the medium-voltage thick gate oxide layer 150 is formed through in-situ steam generation and thermal oxidation.

In some embodiments, before step S1 and for the subsequent process in step S7, an existing 28 high-k metal gate (HKMG) process is employed.

In some embodiments, in step S1, a high-voltage device silicon recess 1011 is formed in a silicon substrate 100 of the high-voltage device region 101 and is filled with a high-voltage device gate oxide;

a top surface of the high-voltage device gate oxide is flush with the upper surface of the silicon substrate 100; and

in step S3, the depth of the medium-voltage device silicon recess 1021 in the silicon substrate 100 is less than the depth of the high-voltage device silicon recess 1011 in the silicon substrate 100.

In some embodiments, the depth of the high-voltage device silicon recess 1011 in the silicon substrate 100 is 400 Å to 500 Å;

the depth of the medium-voltage device silicon recess 1021 in the silicon substrate 100 is 100 Å to 200 Å; and

the thickness of the sacrificial oxide layer 130 is 10 Å to 80 Å.

In some embodiments, the depth of the high-voltage device silicon recess 1011 in the silicon substrate 100 is 460 Å;

the depth of the medium-voltage device silicon recess 1021 in the silicon substrate 100 is 150 Å; and

the thickness of the sacrificial oxide layer 130 is 30 Å.

In the method for manufacturing an integrated structure of a metal-gate MOS transistor in the present application aims to reduce interface defects in the thick oxide layer of the medium-voltage MOS device in the metal gate. Based on existing technical processes, the method uses thermal oxidation to grow the sacrificial oxide layer 130 in the medium-voltage device silicon recess 1021 in the medium-voltage device region 102 of the metal gate. The sacrificial oxide layer 130 is then removed by a wet process. During the thermal oxidation process for growing the sacrificial oxide layer 130, damaged silicon (Si) at a silicon etch-back site is consumed. The formation and removal of the sacrificial oxide layer 130 help eliminate surface damage and a defect induced by a dry etch process to silicon at the position of the medium-voltage device silicon recess, thereby reducing a defect of an interface between Si and SiO₂ in a metal gate medium-voltage device. That facilitates the formation of a low-defect silicon surface and an obtained high-quality gate oxide layer of a metal gate medium-voltage device, improves interface morphology of an overlap region between a drain terminal and a gate terminal of the metal gate medium-voltage devices, and reduces lattice defects and dry etching particles at the surface, so that an interface trap charge density is reduced, thereby reducing a trap-assisted and thermally excited tunneling current and GIDL, and mitigating an impact of the GIDL effect. Ultimately, the objective of reducing the static power consumption of the metal-gate medium-voltage device is achieved. The method for manufacturing an integrated structure of a metal-gate MOS transistor is fully compatible with existing processes and can reduce the GIDL effect without adding additional masks, thereby achieving the objective of reducing the static power consumption of the metal-gate medium-voltage device.

### BRIEF DESCRIPTION OF THE DRAWINGS

To more clearly illustrate the technical solutions of the present application, the accompanying drawings used in the present application are briefly introduced below. Obviously, the drawings described below are merely some embodiments of the present application. Based on these drawings, those skilled in the art can obtain other drawings without the exercise of inventive effort.

FIG. 1 is a schematic diagram of a cross section in which a pad oxide layer is formed according to an embodiment of a method for manufacturing an integrated structure of a metal-gate MOS transistor in the present application.

FIG. 2 is a schematic diagram of a cross section in which a hard mask layer is formed according to an embodiment of a method for manufacturing an integrated structure of a metal-gate MOS transistor in the present application.

FIG. 3 is a schematic diagram of a cross section in which a medium-voltage device silicon recess is formed according to an embodiment of a method for manufacturing an integrated structure of a metal-gate MOS transistor in the present application.

FIG. 4 is a schematic diagram of a cross section in which a sacrificial oxide layer is formed according to an embodiment of a method for manufacturing an integrated structure of a metal-gate MOS transistor in the present application.

FIG. 5 is a schematic diagram of a cross section in which a sacrificial oxide layer is removed according to an embodiment of a method for manufacturing an integrated structure of a metal-gate MOS transistor in the present application.

FIG. 6 is a schematic diagram of a cross section in which a medium-voltage thick gate oxide layer is formed according to an embodiment of a method for manufacturing an integrated structure of a metal-gate MOS transistor in the present application.

Description of reference numeral in the accompanying drawings:

100. Silicon substrate; 110. Pad oxide layer; 104. Shallow trench isolation; 101. High-voltage device region; 102. Medium-voltage device region; 103. Low-voltage device region; 120. Hard mask layer; 1021. Medium-voltage device silicon recess; 130. Sacrificial oxide layer; 140. Photoresist; 150. Medium-voltage thick gate oxide layer; 106. Lightly doped drain; 1011. High-voltage device silicon recess.

### DETAILED DESCRIPTION OF THE DISCLOSURE

The technical solution in the present application is clearly and completely described below in combination with the accompanying drawings. Obviously, the described embodiments are merely some embodiments in the present application and not all embodiments. All other embodiments obtained by those skilled in the art without the exercise of inventive effort based on the embodiments in the present application are within the scope of protection of the present application.

### Embodiment 1

A method for manufacturing an integrated structure of a metal-gate MOS transistor includes the following steps:

S1. forming a pad oxide layer 110 on a silicon substrate 100, referring to FIG. 1;

the silicon substrate 100 being divided into a high-voltage device region 101, a medium-voltage device region 102, and a low-voltage device region 103 through a Shallow trench isolation (STI) 104;

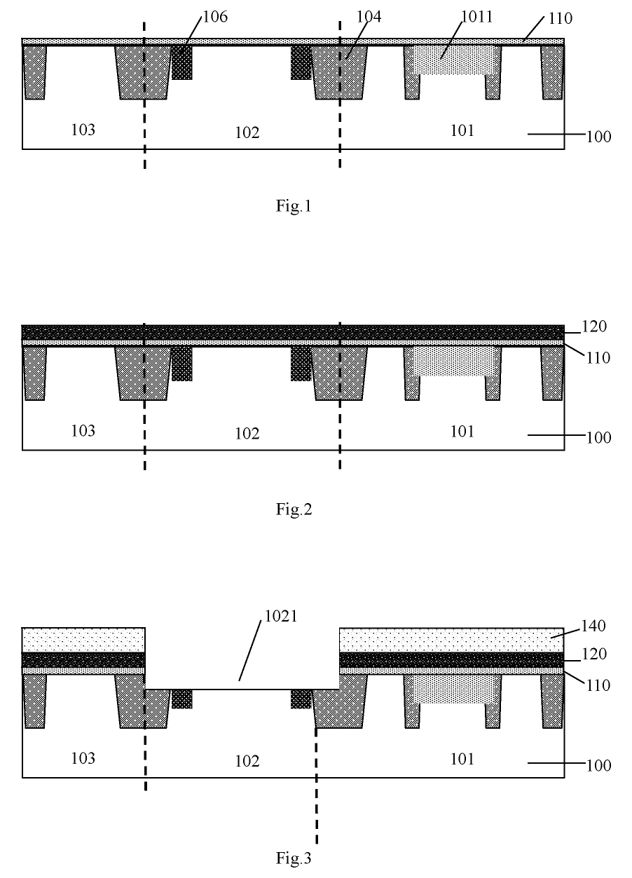

S2. forming a hard mask layer 120 on the pad oxide layer 110; referring to FIG. 2

S3. coating a photoresist 140, followed by photolithograph and dry etching to remove a hard mask layer 120, a pad oxide layer 110, and a top of a silicon substrate 100 in the medium-voltage device region 102 to form a medium-voltage device silicon recess 1021, referring to FIG. 3;

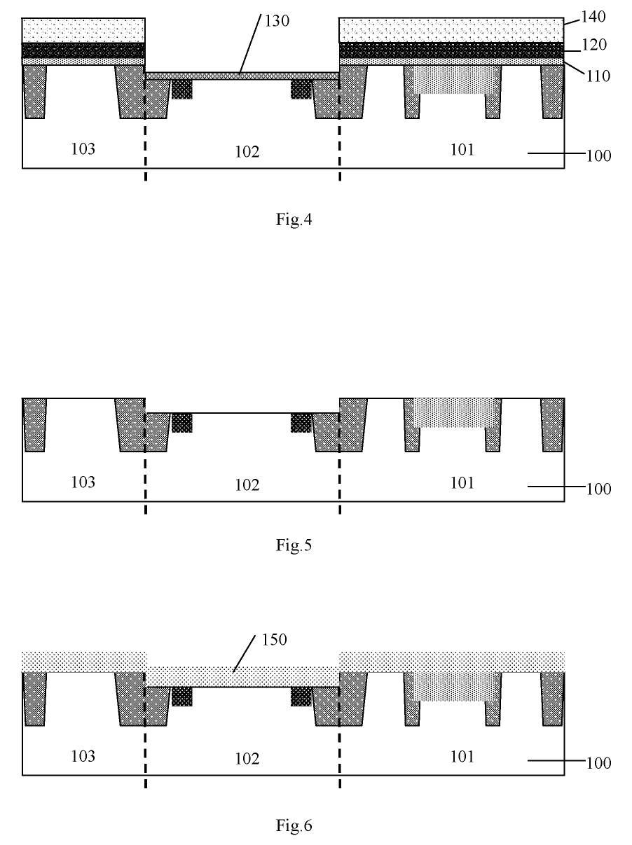

S4. forming a sacrificial oxide layer 130 on a bottom of the medium-voltage device silicon recess 1021 through a thermal oxidation process, referring to FIG. 4;

S5. removing the photoresist 140, followed by a wet process to remove the hard mask layer 120, the pad oxide layer 110 in the low-voltage region and the high-voltage region, and the sacrificial oxide layer 130 in the medium-voltage device silicon recess 1021, referring to FIG. 5;

S6. forming a medium-voltage thick gate oxide layer 150, an upper surface of the medium-voltage thick gate oxide layer 150 within the medium-voltage device silicon recess 1021 being not lower than an upper surface of the silicon substrate 100, referring to FIG. 6; and

S7. performing a subsequent process to complete manufacturing of the integrated structure of the metal-gate MOS transistor.

In the method for manufacturing an integrated structure of a metal-gate MOS transistor in embodiment 1, through the dry etching process, the medium-voltage device silicon recess 1021 is formed, and through the thermal oxidation process, the sacrificial oxide layer 130 is formed at the bottom of the medium-voltage device silicon recess, thereby consuming silicon damaged by the dry etching in the medium-voltage device silicon recess. Then, through the wet etch process, the hard mask layer 120, the pad oxide layers 110 in the low-voltage and the high-voltage region, and the sacrificial oxide layer 130 in the medium-voltage region are removed. The thick oxide layer is then grown as a gate oxide layer of the medium-voltage device.

In the method for manufacturing an integrated structure of a metal-gate MOS transistor in embodiment 1 aims to reduce interface defects in the thick oxide layer of the medium-voltage MOS device in the metal gate. Based on existing technical processes, the method uses thermal oxidation to grow the sacrificial oxide layer 130 in the medium-voltage device silicon recess 1021 in the medium-voltage device region 102 of the metal gate. The sacrificial oxide layer 130 is then removed by a wet process. During the thermal oxidation process for growing the sacrificial oxide layer 130, damaged Si at a silicon etch-back site is consumed. The formation and removal of the sacrificial oxide layer 130 help eliminate surface damage and a defect induced by a dry etch process to silicon at the position of the medium-voltage device silicon recess, thereby reducing a defect of an interface between Si and SiO₂ in a metal gate medium-voltage device. That facilitates the formation of a low-defect silicon surface and an obtained high-quality gate oxide layer of a metal gate medium-voltage device, improves interface morphology of an overlap region between a drain terminal and a gate terminal of the metal gate medium-voltage devices, and reduces lattice defects and dry etching particles at the surface, so that an interface trap charge density is reduced, thereby reducing a trap-assisted and thermally excited tunneling current and GIDL, and mitigating an impact of the GIDL effect. Ultimately, the objective of reducing the static power consumption of the metal-gate medium-voltage device is achieved. The method for manufacturing an integrated structure of a metal-gate MOS transistor in embodiment 1 is fully compatible with existing processes and can reduce the GIDL effect without adding additional masks, thereby achieving the objective of reducing the static power consumption of the metal-gate medium-voltage device.

### Embodiment 2

Based on the method for manufacturing an integrated structure of a metal-gate MOS transistor in embodiment 1, in step S1, light-doped drain 106 ion implantation is performed in a silicon substrate 100 of a medium-voltage device region 102 adjacent to a Shallow trench isolation 104.

Preferably, in step S1, a zero mark is formed on the pad oxide layer 110, the pad oxide layer 110 is used as an alignment layer for the subsequent photolithography.

Preferably, in step S2, SIN is deposited on the pad oxide layer 110 to form a hard mask layer 120.

Preferably, in step S6, a medium-voltage thick gate oxide layer 150 is formed through in-situ steam generation (ISSG) and thermal oxidation.

The method for manufacturing an integrated structure of an MOS transistor having different operating voltages in embodiment 2 starts with a light-doped drain (LDD) ion implantation process for a medium-voltage device region 102 in the related art.

### Embodiment 3

Based on the method for manufacturing an integrated structure of a metal-gate MOS transistor in embodiment 1, before step S1 and for the subsequent process in step S7, an existing 28 nm high-k metal gate (28 nm HKMG) process is employed.

The method for manufacturing an integrated structure of a metal-gate MOS transistor in embodiment 3 is an integrated process method which can manufacture an integrated structure of high-voltage, medium-voltage, and low-voltage MOS transistors on a 28 nm HKMG process platform.

### Embodiment 4

Based on the method for manufacturing an integrated structure of a metal-gate MOS transistor in embodiment 1, in step S1, a high-voltage device silicon recess 1011 is formed in a silicon substrate 100 of the high-voltage device region 101 and is filled with a high-voltage device gate oxide;

a top surface of the high-voltage device gate oxide is flush with the upper surface of the silicon substrate 100; and

in step S3, the depth of the medium-voltage device silicon recess 1021 in the silicon substrate 100 is less than the depth of the high-voltage device silicon recess 1011 in the silicon substrate 100.

Preferably, the depth of the high-voltage device silicon recess 1011 in the silicon substrate 100 is approximately 400 Å to 500 Å (e.g., 460 Å);

the depth of the medium-voltage device silicon recess 1021 in the silicon substrate 100 is approximately 100 Å to 200 Å (e.g., 150 Å); and

the thickness of the sacrificial oxide layer 130 is 10 Å to 80 Å (e.g., 30 Å).

The above merely describes preferred embodiments of the present application and is not intended to limit the application. Any modifications, equivalent substitutions, improvements, etc., made within the spirit and principle of the present application should be included within the scope of protection of the present application.

What is claimed is:

1. A method for manufacturing an integrated structure of a metal-gate MOS transistor, comprising the following steps:
1S. forming a pad oxide layer on a silicon substrate;
the silicon substrate being divided into a high-voltage device region, a medium-voltage device region, and a low-voltage device region through a Shallow trench isolation;
2S. forming a hard mask layer on the pad oxide layer;
3S. coating a photoresist, followed by photolithograph and dry etching to remove a hard mask layer, a pad oxide layer, and a top of a silicon substrate in the medium-voltage device region to form a medium-voltage device silicon recess;
4S. forming a sacrificial oxide layer on a bottom of the medium-voltage device silicon recess through a thermal oxidation process;
5S. removing the photoresist, followed by a wet process to remove the hard mask layer, the pad oxide layer in the low-voltage region and the high-voltage region, and the sacrificial oxide layer in the medium-voltage device silicon recess;
6S. forming a medium-voltage thick gate oxide layer, an upper surface of the medium-voltage thick gate oxide layer within the medium-voltage device silicon recess being not lower than an upper surface of the silicon substrate; and
7S. performing a subsequent process to complete manufacturing of the integrated structure of the metal-gate MOS transistor.

2. The method for manufacturing an integrated structure of a metal-gate MOS transistor according to claim 1, wherein,
in step S1, light-doped drain ion implantation is performed in a silicon substrate of the medium-voltage device region adjacent to the Shallow trench isolation.

3. The method for manufacturing an integrated structure of a metal-gate MOS transistor according to claim 1, wherein,
in step S1, a zero mark is formed on the pad oxide layer, the pad oxide layer is used as an alignment layer for the subsequent photolithography.

4. The method for manufacturing an integrated structure of a metal-gate MOS transistor according to claim 1, wherein,
in step S2, SIN is deposited on the pad oxide layer to form a hard mask layer.

5. The method for manufacturing an integrated structure of a metal-gate MOS transistor according to claim 1, wherein,
in step S6, the medium-voltage thick gate oxide layer is formed through in-situ steam generation and thermal oxidation.

6. The method for manufacturing an integrated structure of a metal-gate MOS transistor according to claim 1, wherein,
before step S1 and for the subsequent process in step S7, an existing 28HKMG process is employed.

7. A method for manufacturing an integrated structure of a metal-gate MOS transistor according to claim 1, wherein,
in step S1, a high-voltage device silicon recess is formed in a silicon substrate of the high-voltage device region and is filled with a high-voltage device gate oxide;
a top surface of the high-voltage device gate oxide is flush with the upper surface of the silicon substrate; and
in step S3, the depth of the medium-voltage device silicon recess in the silicon substrate is less than the depth of the high-voltage device silicon recess in the silicon substrate.

8. The method for manufacturing an integrated structure of a metal-gate MOS transistor according to claim 7, wherein:
the depth of the high-voltage device silicon recess in the silicon substrate is 400 Å to 500 Å;
the depth of the medium-voltage device silicon recess in the silicon substrate is 100 Å to 200 Å; and
the thickness of the sacrificial oxide layer is 10 Å to 80 Å.

9. The method for manufacturing an integrated structure of a metal-gate MOS transistor according to claim 8, wherein,
the depth of the high-voltage device silicon recess in the silicon substrate is 460 Å;
the depth of the medium-voltage device silicon recess in the silicon substrate is 150 Å; and
the thickness of the sacrificial oxide layer is 30 Å.
